(19) United States
(12) Patent Application Publication
(10) Pub. No.: US 2010/0061153 A1
(43) Pub. Date: Mar. 11, 2010

(54) Refresh Method for a Non-volatile Memory

(76) Inventors: Ching-Fang Yen, Taipei County (TW); Che-Heng Lai, Kaohsiung City (TW); Chih-Yuan Cheng, Taipei City (TW)

Correspondence Address: NORTH AMERICA INTELLECTUAL PROPERTY CORPORATION, P.O. BOX 506, MERRIFIELD, VA, 22116, US

(21) Appl. No.: 12/344,288

(22) Filed: Dec. 26, 2008

(30) Foreign Application Priority Data
Sep. 9, 2008 (TW) 097134516

(51) Int. Cl. G11C 16/06

(52) U.S. Cl. 365/185.25; 365/185.29; 365/185.18

(57) ABSTRACT

A refresh method for a non-volatile memory for preventing disturb phenomenon includes dividing a plurality of sectors of a block of the non-volatile memory into a plurality of groups, determining a first group of the plurality of groups according to a first value when a first sector of the plurality of sectors is performed an erase operation, and reading and rewriting data of sectors of the first group.

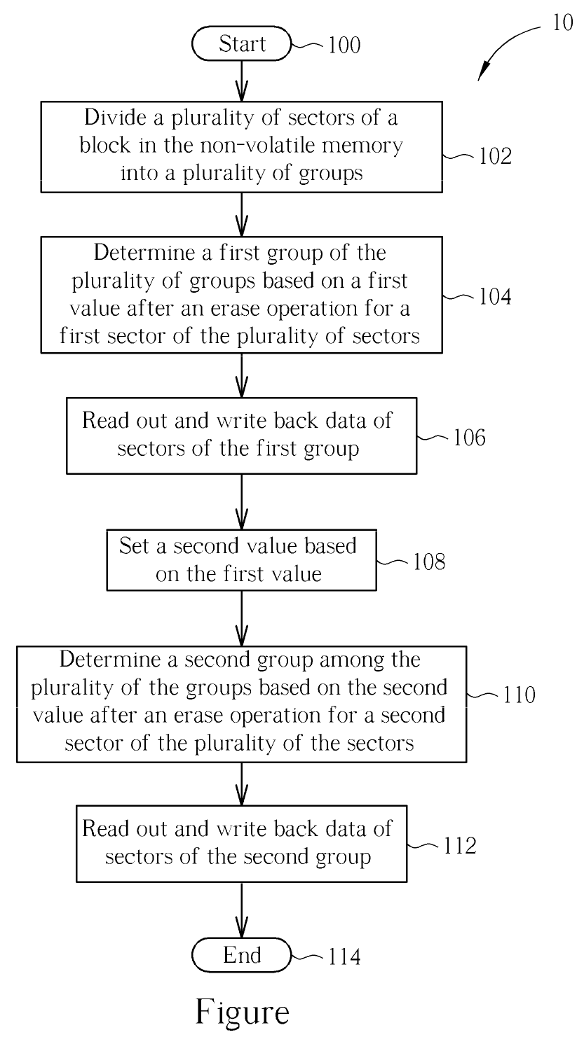

### BACKGROUND OF THE INVENTION

1. Field of the Invention

The present invention is related to a refresh method for a non-volatile memory, and more particularly, to a refresh method for a non-volatile memory to reduce operating time and production cost.

2. Description of the Prior Art

In the modern society, the tremendous flow of information has become part of people's everyday life. For easy management of information, a memory device for storing information has become a significant subject for development in the information technology (IT) industry. This is especially obvious for a flash memory, for its low power consumption, high working speed, re-programmability, non-volatility and no moving mechanical parts. Thus, the flash memory has been playing an important role among all the memory devices.

The flash memory can be further classified into a floating gate flash memory and a split gate flash memory. Because the floating gate flash memory has merits, such as smaller area for a unit memory cell, faster access speed, and good endurance for Program and Erase commands, the floating gate flash memory is being used in portable electronic devices, computer input/output devices and many consumer devices. In a traditional floating gate flash memory, memory cells in the same P-well are set to be in the same sector, and an insulating layer is set around the P-well, such that the cells in the different sectors can be electrically isolated. The use of the insulation layer can decrease the chip area efficiency of the flash memory; that is to say, the more chip area used by the insulation layer, the less chip area can be used for the memory unit. Therefore, the area of the P-well is usually built to be larger for increasing the chip area efficiency of the memory device.

If all of the memory cells in the same P-well were further divided into multiple sectors of few memory capacities, then the sectors in the same P-well become electrically correlated. In other words, when an Erase command is issued to perform an erase function to a specific sector, the other sectors in the same P-well will be disturbed. When the disturb phenomena accumulates after certain times, data stored in the memory cells will change from “0” to “1” (on the contrary, “1” won't be changed to “0”), and therefore the memory cells need to be refreshed for avoiding the disturb phenomena. The method for refreshing the memory cells in the same P-well is to read out all the data in the same P-well and then written back, but this will need extra memory buffers, and the overall cost is then increased.

Another method in the prior art is to read all the data in the same P-well twice, and compare the data to see whether they are identical; if the two sets of data are not identical, then the memory will perform a refresh process. However, this method is time-consuming, and more complex to implement, and the cost is also increased.

### SUMMARY OF THE INVENTION

It is therefore a primary objective of the claimed invention to provide a refresh method for a non-volatile memory.

The present invention discloses a refresh method, for a non-volatile memory to prevent disturb, which comprises dividing a plurality of sectors of a block in the non-volatile memory into a plurality of groups, determining a first group of the plurality of groups based on a first value after an erase operation for a first sector of the plurality of sectors, and reading out and writing back data of sectors of the first group.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The figure illustrates a schematic diagram of a refresh flowchart in accordance with an embodiment of the present invention.

### DETAILED DESCRIPTION

Please refer to the figure, which illustrates a schematic diagram of a refresh process 10 in accordance with an embodiment of the present invention. The refresh process 10 is used for a non-volatile memory, like a flash memory, and is designed for preventing the disturb phenomena. The refresh process 10 comprises the following steps:

Step 100: Start.

Step 102: Divide a plurality of sectors of a block in the non-volatile memory into a plurality of groups.

Step 104: Determine a first group of the plurality of groups based on a first value after an erase operation for a first sector of the plurality of sectors.

Step 106: Read out and write back data of sectors of the first group.

Step 108: Set a second value based on the first value.

Step 110: Determine a second group among the plurality of the groups based on the second value after an erase operation for a second sector of the plurality of the sectors.

Step 112: Read out and write back data of sectors of the second group.

Step 114: End

According to the refresh process 10, the embodiment of the present invention is first to divide the sectors of a block in the non-volatile memory into a plurality of groups. After an erase operation has completed for a sector, the embodiment of the present invention determines the first group according to the first value, and takes the first group to perform the refresh operation, which means reading out and writing back data of sectors of the first group. After finishing the refresh operation of the first group, and when another sector in the block has completed the erase operation, the present invention determines the second group based upon the second value to perform the refresh operation. The second value is decided based on the first value; for example, the second value is equal to the first value plus 1. On the other hand, besides the first group, the refresh operation of the other group is performed in sequence according to the erase operation of the sector. Under this procedure, all the sectors in the block are refreshed in sequence, such that the “disturb” phenomena can be avoided.

Briefly speaking, the present invention divides the sectors of a block into a plurality of groups; whenever an erase operation has completed for a sector, a refresh operation is performed for the sectors of the group. Following this procedure, when a specific number (equals the number of groups) of sectors in a block complete the erase operation, all the sectors in the block can complete the refresh operation accordingly. In comparison, the prior art must read out all the data in the same p-well and then written back, or check whether two sets of the data are equal. Therefore, the present invention not only saves operating time, but also it reduces the cost owing to less-complex installation.

Noteworthily, in the refresh process 10, the terms like “a first” or “a second” means only for representing different objects, and not for implying the sequence of the objects. Those skilled in the art can make modifications according to different systems. Preferably, the first value is a random number, or selected randomly from a plurality of predefined values, where each predefined value is corresponding to a group, and the second value is an incremental value of the first value, and so on. In other words, the present invention randomly selects the group for the first refresh operation, and then refreshes every other following group or groups.

On the other hand, the methods of dividing sectors or the number of groups are not restricted to any specific way; for example, if the number of groups is 2, the even-numbered word lines in the block can be defined as the first group, and corresponding to “0”; meanwhile, the odd-numbered word lines in the block can be defined as the second group, and corresponding to “1”. As a result, when a sector completes the erase operation for the first time, if the first value equals “0”, then the present invention will perform the refresh operation to the sectors with the even-numbered word lines; after another sector completes the erase operation, the odd-numbered word line in the block will be refreshed subsequently. On the contrary, when a sector completes the erase operation for the first time, and if the first value equals “1”, then the present invention will perform the refresh operation to the sectors with the odd-numbered word lines; after another sector completes the erase operation, the even-numbered word lines in the block will be refreshed subsequently. In other words, no matter what the first value might be, after two times of erase operation, all the refresh operations to the sectors in the block can be completed. Therefore, compared with the prior art, the present invention can save not only total time of operation, but also operating cost because of easier way of realization.

Certainly, the sectors in the same block cannot only be divided into two groups, it is also possible to divide the block into three or more than three groups, and the methods of operation can be inferred from the description above. That is, when a sector completes the erase operation for the first time, the other groups can be refreshed in a proper sequence. Taking three groups A, B and C as an example, if the sector A is randomly selected as the sector to perform the erase operation for the first time, then the flowing sequence for the refresh operation can be arranged as B, and then C; if the sector B is randomly selected as the sector to perform the erase operation for the first time, then the flowing sequence for the refresh operation can be arranged as C, and then A; if the sector C is randomly selected as the sector to perform the erase operation for the first time, then the flowing sequence for the refresh operation can be arranged as A, and then B.

To sum up, the present invention is to divide the sectors of a block into a plurality of groups, and as the erase operation is performed to a sector, the refresh operation is performed to every group, so as to perform the refresh operation to all the sectors. Therefore, compared with the prior art, the present invention can save time and the total cost can be reduced because of easier implementation.

Those skilled in the art will readily observe that numerous modifications and alterations of the device and method may be made while retaining the teachings of the invention.

What is claimed is:

1. A refresh method for a non-volatile memory, for preventing disturb, the refresh method comprising:
dividing a plurality of sectors of a block in the non-volatile memory into a plurality of groups;
determining a first group of the plurality of groups based on a first value after an erase operation for a first sector of the plurality of sectors; and
reading out and writing back data of sectors of the first group.

2. The refresh method of claim 1, wherein the first value is a random number.

3. The refresh method of claim 1 further comprising randomly selecting the first value among a plurality of predefined values corresponding to the plurality of the groups.

4. The refresh method of claim 1 further comprising:
setting a second value based on the first value;
determining a second group among the plurality of the groups based on the second value after an erase operation for a second sector of the plurality of the sectors; and
reading out and writing back data of sectors of the second group.

5. The refresh method of claim 4, wherein the second value equals the first value plus 1.

6. The refresh method of claim 4, wherein a number of the plurality of groups is 2.

7. The refresh method of claim 6, wherein the first group comprises sectors corresponding to even-numbered word lines in the block.

8. The refresh method of claim 6, wherein the second group comprises sectors corresponding to odd-numbered word lines in the block.

9. The refresh method of claim 1, wherein the non-volatile memory is a flash memory.
